(19) United States
(12) Patent Application Publication
(10) Pub. No.: US 2024/0379544 A1
(43) Pub. Date: Nov. 14, 2024

(54) LOW RESISTANCE STAIRCASE RIVET CONTACT USING METAL-TO-METAL STRAP CONNECTION

(71) Applicant: Micron Technology, Inc., Boise, ID (US)

(72) Inventors: Darwin A. Clampitt, Wilder, ID (US); Martin Jared Barclay, Middleton, ID (US); Haoyu Li, Boise, ID (US)

(21) Appl. No.: 18/654,618

(22) Filed: May 3, 2024

Related U.S. Application Data
(60) Provisional application No. 63/465,663, filed on May 11, 2023.

(51) Int. Cl. H01L 23/528; H01L 21/768; H10B 41/27; H10B 43/27

(52) U.S. Cl. CPC H01L 23/528; H01L 21/76802; H01L 21/76877; H10B 41/27; H10B 43/27

(57) ABSTRACT

Methods, systems, and devices for low resistance staircase rivet contact using metal-to-metal strap connection are described. The described techniques provide for usage of a metallic material that adheres to a dielectric material when deposited via a chemical vapor deposition (CVD) process or atomic layer deposition (ALD) process to connect to a word line contact. For example, a strap may be formed between a layer of conductive material and a word line contact that extends at least partially through a stack of layers, and may be filled with such a metallic material. Such techniques may support a connection between the word line contact and the layer of conductive material without usage of a liner material, which may mitigate a resistance of the connection.

### CROSS REFERENCE

The present Application for Patent claims priority to U.S. Patent Application No. 63/465,663 by Clampitt et al., entitled “LOW RESISTANCE STAIRCASE RIVET CONTACT USING METAL-TO-METAL STRAP CONNECTION” filed May 11, 2023, which is assigned to the assignee hereof, and which is expressly incorporated by reference in its entirety herein.

### TECHNICAL FIELD

The following relates to one or more systems for memory, including low resistance staircase rivet contact using metal-to-metal strap connection.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory array that supports low resistance staircase rivet contact using metal-to-metal strap connection in accordance with examples as disclosed herein.

FIG. 2 shows a top view of an example of a memory array that supports low resistance staircase rivet contact using metal-to-metal strap connection in accordance with examples as disclosed herein.

FIGS. 3A and 3B show side views of an example of a memory array that supports low resistance staircase rivet contact using metal-to-metal strap connection in accordance with examples as disclosed herein.

FIG. 4 shows an example of a layout that supports low resistance staircase rivet contact using metal-to-metal strap connection in accordance with examples as disclosed herein.

FIG. 5 shows an example of a layout that supports low resistance staircase rivet contact using metal-to-metal strap connection in accordance with examples as disclosed herein.

FIG. 6 shows an example of a layout that supports low resistance staircase rivet contact using metal-to-metal strap connection in accordance with examples as disclosed herein.

FIG. 7 shows a block diagram of a manufacturing system that supports low resistance staircase rivet contact using metal-to-metal strap connection in accordance with examples as disclosed herein.

FIG. 8 shows a flowchart illustrating a method or methods that support low resistance staircase rivet contact using metal-to-metal strap connection in accordance with examples as disclosed herein.

### DETAILED DESCRIPTION

Memory devices may include one or more arrays of memory cells and supporting circuitry formed over a substrate for operating and accessing the memory cells. For example, a memory device may include one or more memory arrays that have multiple levels of memory cells, where a level may refer to a plane above and, in some cases, parallel to the substrate (e.g., in a horizontal direction). In some cases, such architectures may include access circuitry formed from one or more levels. For example, a stack of materials may be formed and may alternate between a dielectric material and a metallic material (e.g., used for word lines), where layers may be accessed via a contact cavity (e.g., extending through the stack of materials). In some examples, the contact cavity may be filled with a metallic material during a process step in which some of the dielectric material between the word lines or on an upper surface of the stack of materials may be exposed. The metallic material (e.g., Tungsten) may fail to adhere directly to a surface of the dielectric material (e.g., an oxide material). If the metallic material is deposited directly on the surface including the exposed portions of the dielectric material, portions of the metallic material that do not adhere to the dielectric material may cause contamination of other portions of the stack of materials. Thus a liner material (e.g., TiN) may be deposited prior to the metallic material to support the metallic material adhering to the stack of materials. However, usage of a such a liner material may result in a portion of the liner material separating the metallic material of the contact and the metallic material of the word line, which may increase a resistance between the contact and the word line.

To support mitigating resistance at a word line contact, a different metallic material (e.g., Molybdenum or other suitable metal) may be deposited to a contact cavity without depositing a liner material (e.g., due to adhering to the oxide material). In some cases, a strap may be formed at the layer associated with the contact cavity by transforming a sacrificial material to a different sacrificial material, which may support separate etching of other layers of the sacrificial material and the strap for the word line contact. For example, a first set of layers that correspond to the metallic material (e.g., layers for word line contacts) may initially be formed from a sacrificial material (e.g., SiN). In some cases, a cavity may be formed to expose a layer of the sacrificial material, and the exposed sacrificial material may be transformed to the different sacrificial material (e.g., SiCN). By transforming the exposed layer, the other layers of the sacrificial material may be etched (e.g., pulled back from the cavity) independently from the exposed layer. The exposed layer of the different sacrificial material (e.g., the strap) may then be filled with the different metallic material (e.g., Molybdenum) via the contact cavity or via a slit (e.g., used to exhume and fill the word line structures). In some cases, such techniques may support a reduced resistance between the contact material and the word line material.

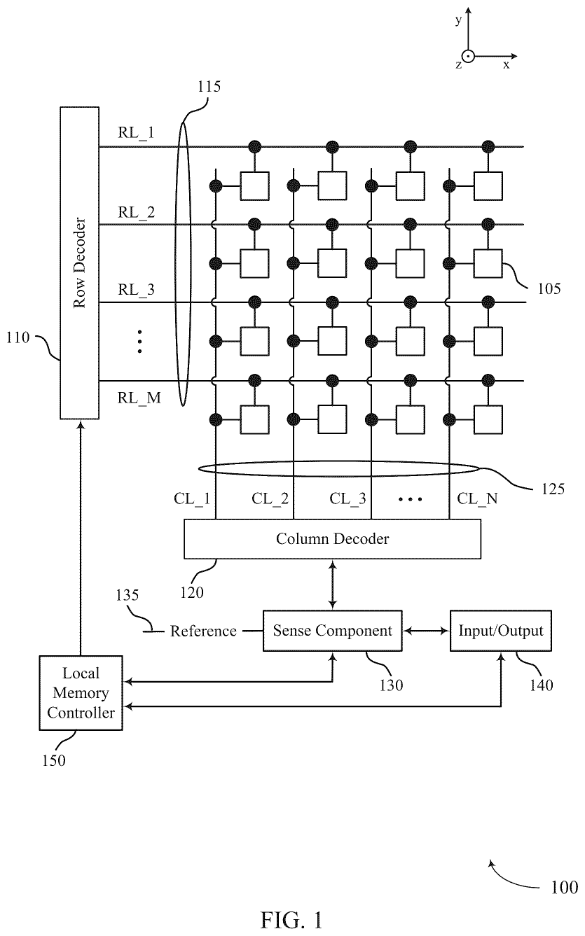

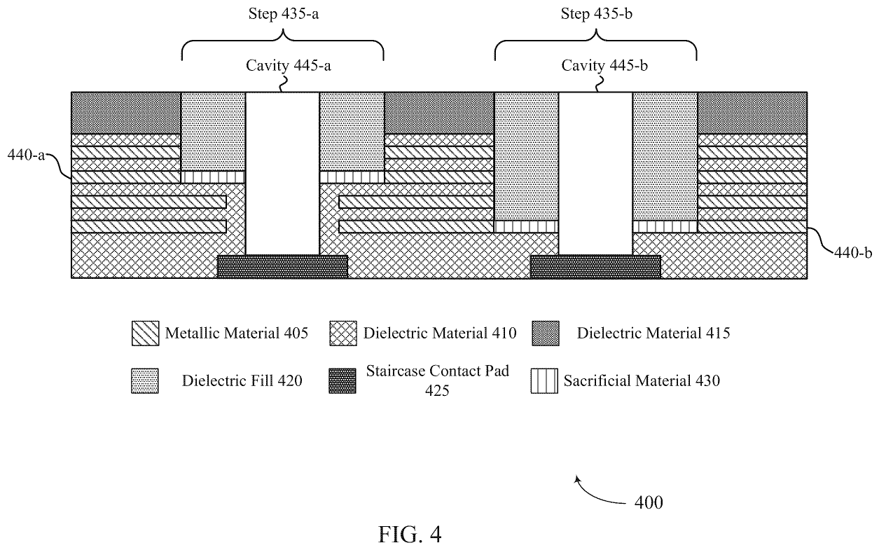

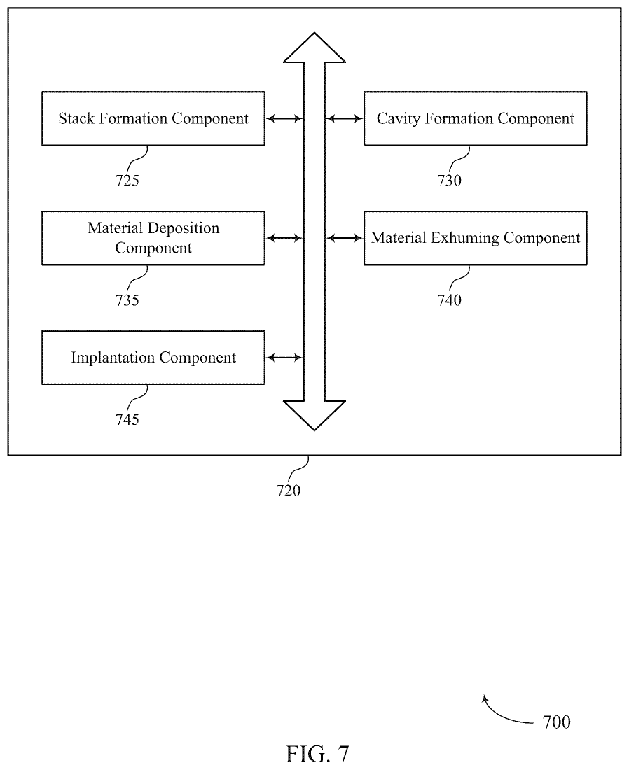

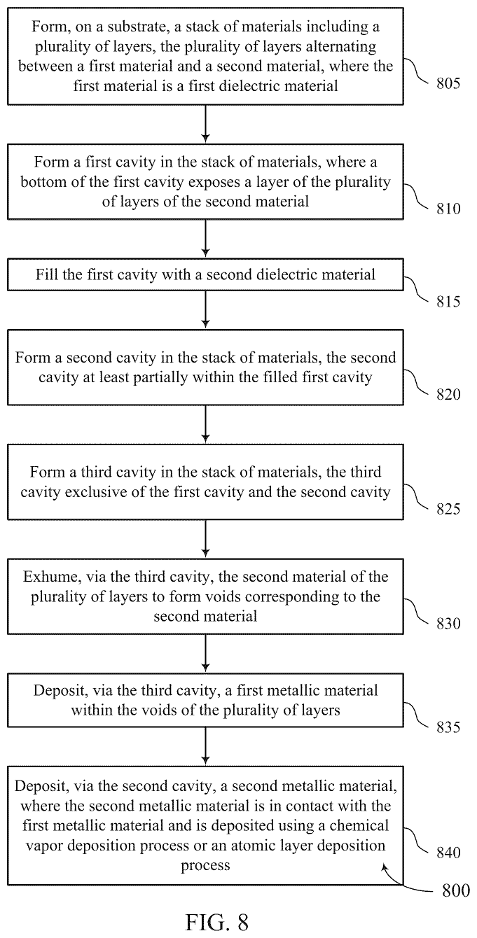

Features of the disclosure are initially described in the context of memory devices and arrays with reference to FIGS. 1, 2, 3A, and 3B. Features of the disclosure are described in the context layouts with reference to FIGS. 4 through 6. These and other features of the disclosure are further illustrated by and described with reference to an apparatus diagram and flowcharts that relate to low resistance staircase rivet contact using metal-to-metal strap connection as described with reference to FIGS. 7 and 8.

FIG. 1 shows an example of a memory device 100 that supports low resistance staircase rivet contact using metal-to-metal strap connection in accordance with examples as disclosed herein. In some examples, the memory device 100 may be referred to as or include a memory die, a memory chip, or an electronic memory apparatus. The memory device 100 may be operable to provide locations to store information (e.g., physical memory addresses) that may be used by a system (e.g., a host device coupled with the memory device 100, for writing information, for reading information).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 105, for self-selecting memory cells 105), some or all of the set of logic states supported by the memory cells 105 may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting or thresholding memory cell 105 may have a high threshold voltage state and a low threshold voltage state. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

In some cases, access operations for one or more memory cells 105 may be performed via a word line contact, which may extend through a stack of materials to contact one or more word lines. For example, the stack of materials may include a staircase structure where each step of the staircase corresponds to a respective layer of conductive material and a respective contact opening. In some cases, a connection between the contact opening and the layer of conductive material may be achieved by depositing a metallic material that extends between the layer and the contact opening. However, the metallic material may be deposited on top of a dielectric material, and some metallic materials (e.g., Tungsten) may flake or otherwise fail to adhere to the dielectric material. In such cases, a liner material may be deposited in between the metallic material and the dielectric material, which may increase a resistance between the metallic material of the contact opening and the layer of conductive material.

To support a low resistance connection between the metallic material of a contact opening and a layer of conductive material, a metallic material that adheres to the dielectric material without usage of a liner material may be used. For example, a strap extending between the contact opening and the conductive layer may be filled with such a metallic material, which may be Molybdenum, or other metallic material that adheres to the dielectric material when deposited via a chemical vapor deposition (CVD) process or an atomic layer deposition (ALD) process.

In addition to applicability in memory systems as described herein, techniques for low resistance staircase rivet contact using metal-to-metal strap connection may be generally implemented to improve the performance (including gaming) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by improving a density of memory arrays, which may improve computing power and efficiency, among other benefits.

The memory device 100 may include any quantity of non-transitory computer readable media that support low resistance staircase rivet contact using metal-to-metal strap connection. For example, a local memory controller 150, a row decoder 110, a column decoder 120, a sense component 130, or an input/output component 140, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

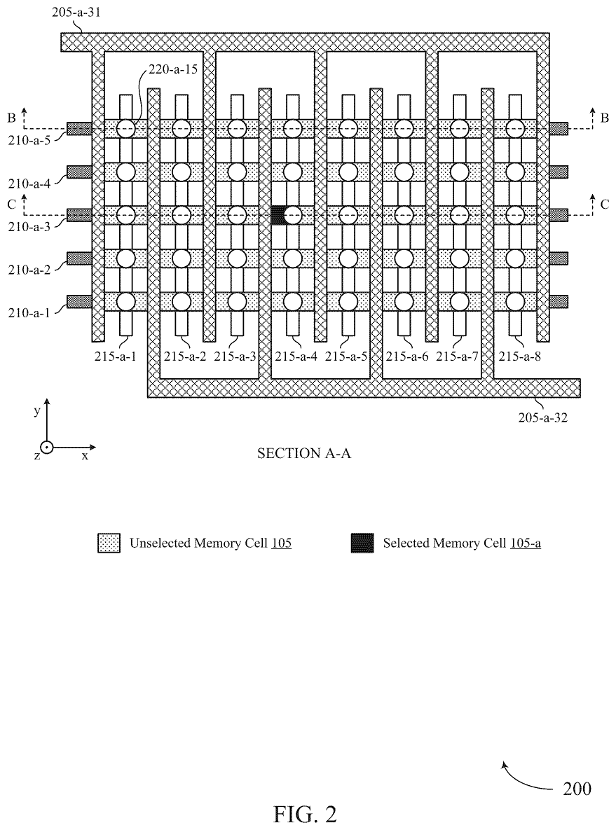

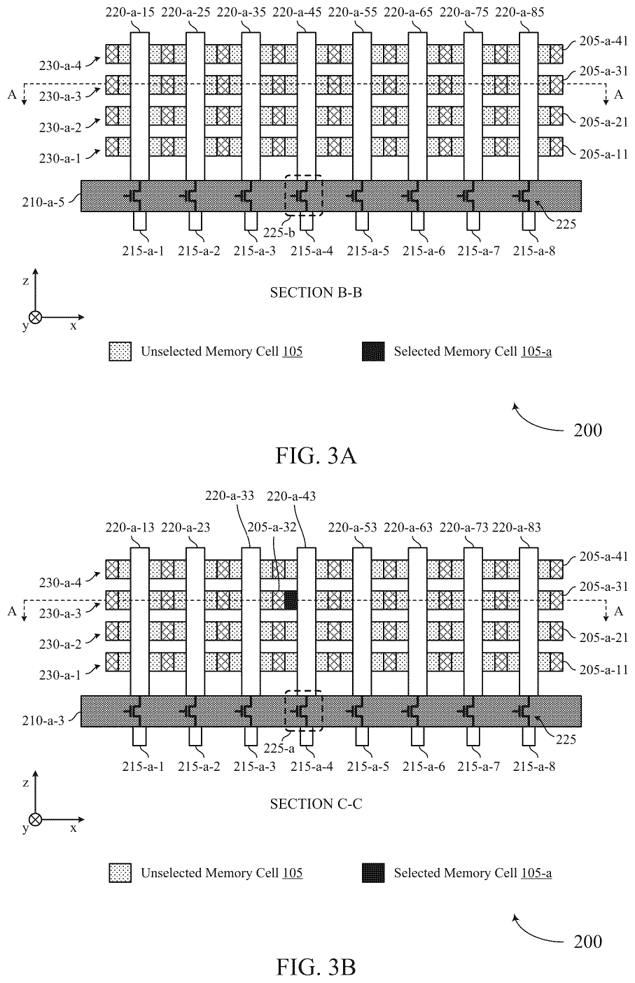

FIGS. 2, 3A, and 3B show an example of a memory array 200 that supports low resistance staircase rivet contact using metal-to-metal strap connection in accordance with examples as disclosed herein. The memory array 200 may be included in a memory device 100, and illustrates an example of a three-dimensional arrangement of memory cells 105 that may be accessed by various conductive structures (e.g., access lines). FIG. 2 illustrates a top section view (e.g., SECTION A-A) of the memory array 200 relative to a cut plane A-A as shown in FIGS. 3A and 3B. FIG. 3A illustrates a side section view (e.g., SECTION B-B) of the memory array 200 relative to a cut plane B-B as shown in FIG. 2. FIG. 3B illustrates a side section view (e.g., SECTION C-C) of the memory array 200 relative to a cut plane C-C as shown in FIG. 2. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2, 3A, and 3B. Although some elements included in FIGS. 2, 3A, and 3B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers, as illustrated in FIGS. 3A and 3B). In some examples, the z-direction may be orthogonal to a surface of a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200 may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a column decoder 120 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 3A, may be biased with a voltage equal to or similar to an access bias (e.g., −V_{access}/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=Vread, which may be a positive voltage or a negative voltage) across the memory cell 105. In some examples, a logic state of the memory cell 105 may be evaluated based on whether the memory cell 105 thresholds in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

In some examples, such techniques may be extended to a memory architecture supporting NAND memory cells. For example, the memory cells 105 may be connected in a 3D NAND configuration. In such an example, a pillar 220 may be an example of a string of the memory cells 105, where multiple strings may form a block of memory cells 105 (e.g., a collection of pages of the memory cells 105). In some examples, each string may include a set of memory cells 105 connected in series (e.g., along the z-direction, in which a drain of one memory cell 105 in the string may be coupled with a source of another memory cell 105 in the string). Each memory cell 105 in a string may be associated with a different word line 205, such that a quantity of word lines 205 in the memory architecture may be equal to the quantity of memory cells 105 in a string. Accordingly, a string may include memory cells 105 from multiple pages, and a page may include memory cells 105 from multiple strings.

In some cases, access operations for one or more memory cells 105 may be performed via a word line contact, which may extend through a stack of materials to contact one or more word line gates. For example, the stack of materials may include a staircase structure where each step of the staircase corresponds to a respective layer of conductive material and a respective contact opening. In some cases, the contact opening may be filled with a metallic material during a process step in which some of the dielectric material between the word lines or on an upper surface of the stack of materials may be exposed. In some cases, a connection between the contact opening and the layer of conductive material may be achieved by depositing a metallic material that extends between the layer the contact opening. However, the metallic material may be deposited on top of a dielectric material, and some metallic materials (e.g., Tungsten) may flake or otherwise fail to directly adhere to the dielectric material. If the metallic material is deposited directly on the surface including the exposed portions of the dielectric material, portions of the metallic material that do not adhere to the dielectric material may cause contamination of other portions of the stack of materials. In such cases, a liner material may be deposited in between the metallic material and the dielectric material, which may increase a resistance between the metallic material of the contact opening and the layer of conductive material.

To support a low resistance connection between the metallic material of a contact opening and a layer of conductive material, a metallic material that adheres to the dielectric material without usage of a liner material may be used. For example, a strap extending between the contact opening and the conductive layer may be filled with such a metallic material, which may be Molybdenum, or other metallic material that adheres to the dielectric material when deposited via a CVD process or an ALD process.

FIG. 4 shows an example of a layout 400 that supports low resistance staircase rivet contact using metal-to-metal strap connection in accordance with various aspects of the present disclosure. The layout 400 may illustrate an example of a first set of manufacturing operations for a memory device that supports a metal-to-metal strap connection at a word line contact as described herein. In some cases, the layout 400 may include one or more layers of a metallic material 405 (e.g., layers forming word lines 205 as described with reference to FIGS. 2, 3A, and 3B), one or more layers of a dielectric material 410, a top layer of a dielectric material 415, a dielectric fill 420 (e.g., a same or different material as the dielectric material 415 and the dielectric material 410), one or more staircase contact pads 425, a sacrificial material 430 corresponding to one or more straps for word line contacts, or any combination thereof. It should be noted that the layout 400 may support any quantity of layers, any type of material, and various patterns of the materials, among other examples. The layout 400 may include a cross section view of a memory device associated with the first set of manufacturing operations.

In some examples, the first set of manufacturing operations may include forming a stack of materials including multiple layers. The multiple layers may alternate between a first material (e.g., the dielectric material 410) and a second material (e.g., a first sacrificial material, which may be a dielectric material). In some cases, a staircase structure may be formed by cutting a cavity (e.g., a first cavity) into the stack of materials to a layer that is being contacted. For example, a first step 435-a of the staircase may be formed by cutting a cavity that extends to a layer 440-a of the stack of materials and a second step 435-b of the staircase may be formed by cutting a cavity that extends to a layer 440-b of the stack of materials. In some cases, the cavities formed for each step 435 may expose a portion of the corresponding layer 440 (e.g., a layer of the first sacrificial material). It should be noted that while the layout 400 illustrates two steps of the staircase structure, any quantity of steps may be formed for any quantity of corresponding layers.

In some cases, the first set of manufacturing operations may include transforming the exposed layer of the first sacrificial material to a different sacrificial material via first cavity. For example, an operation may be performed on the exposed layer to transform the first sacrificial material of the exposed layer to a second sacrificial material, which may be the sacrificial material 430. For example, the exposed layer of the first sacrificial (e.g., SiN) material may be implanted (e.g., with carbon) to form the second sacrificial material (e.g., SiCN) within the portion of a layer 440 exposed by the cavity. In some cases, the first sacrificial material and the second sacrificial material may be etched using different chemistries (e.g., selectively etched). In some cases, the cavity may be filled with the dielectric fill 420 subsequent to transforming the exposed layer to the second sacrificial material (e.g., the sacrificial material 430).

In some cases, the first set of manufacturing operations may include cutting a second cavity at least partially within the filled first cavity to form a cavity 445 (e.g., a second cavity for forming a word line contact for each step 435). For example, a cavity 445-a may be formed for the step 435-a and a cavity 445-b may be formed for the step 435-b. In some examples, a cavity 445 may extend to the exposed layer of the corresponding step 435 (e.g., a top down contact). For example, the cavity 445-a may extend to the layer 440-a and the cavity 445-b may extend to the layer 440-b (e.g., terminating at the exposed layer).

In some other examples, the cavity 445 may extend through the stack to a corresponding staircase contact pad 425 (e.g., a rivet contact). In such an example, an additional etching step (e.g., subsequent to forming the second cavity) may be performed to pull back one or more layers of the first sacrificial material that extend to the cavity 445. As an example, for the step 435-a, one or more layers of the first sacrificial material that are below the layer 440-a may be etched to create cavities between the one or more layers and the cavity 445-a (e.g., to prevent the one or more layers from contacting the word line contact). In some cases, the cavities formed between the one or more layers and the cavity 445 may be filled with a dielectric material, which may be the dielectric material 410 (e.g., the first material of the alternating layers).

In some examples, the first set of manufacturing instructions may include forming a slit (e.g., a third cavity) to support exhuming the first sacrificial material from the stack of materials. For example, the slit may be formed in a location that is exclusive of the first cavity and the second cavity (e.g., in a space between steps 435) and may be cut in a plane that is parallel or orthogonal to the cross section illustrated by the layout 400.

In some examples, the first set of manufacturing instructions may include exhuming, via the slit, the first sacrificial material from the stack of materials. For example, the first sacrificial material may be exhumed to form voids corresponding to the layers of the first sacrificial material. In some cases, the second sacrificial material (e.g., associated with the contact strap) may not be exhumed with the first sacrificial material (e.g., due to having a different etch chemistry).

In some examples, the first set of manufacturing instructions may include depositing, via the slit, the metallic material 405 within the voids corresponding to the layers of the first sacrificial material. For example, the metallic material 405 may be deposited to create word lines between the layers of the dielectric material 410. Such operations may result in an arrangement of materials as illustrated in the layout 400.

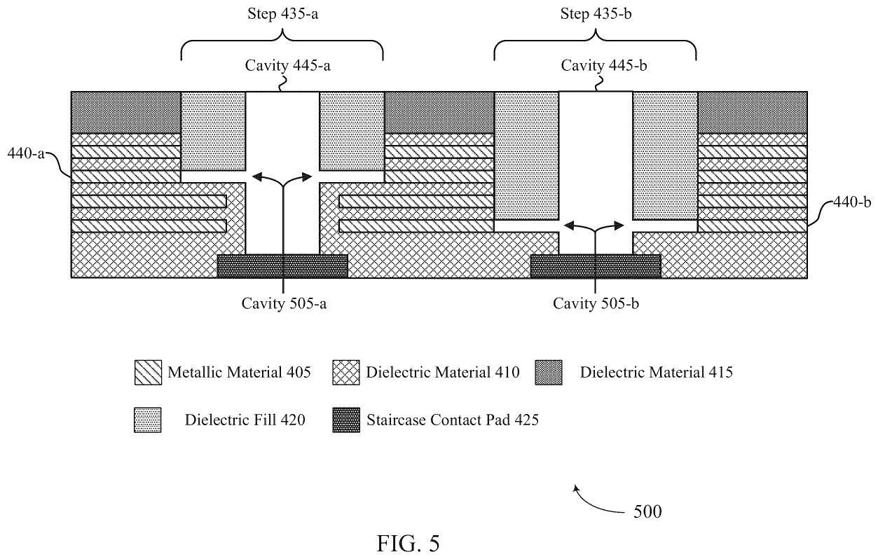

FIG. 5 shows an example of a layout 500 that supports low resistance staircase rivet contact using metal-to-metal strap connection in accordance with various aspects of the present disclosure. The layout 500 may illustrate an example of a second set of manufacturing operations for a memory device that supports a metal-to-metal strap connection at a word line contact as described herein. In some cases, the second set of manufacturing operations may follow the first set of manufacturing operations described with reference to FIG. 4 (e.g., applying the second set of manufacturing operations to the layout 400 may result in the layout 500). The layout 500 may include one or more aspects of the layout 400, such as one or more layers of the metallic material 405, one or more layers of the dielectric material 410, a top layer of the dielectric material 415, the dielectric fill 420 (e.g., a same or different material as the dielectric material 415 and the dielectric material 410), the staircase contact pad 425, or any combination thereof. It should be noted that the layout 500 may support any quantity of layers, any type of material, and various patterns of the materials, among other examples. The layout 500 may include a cross section view of a memory device associated with the second set of manufacturing operations.

The layout 500 may support a staircase structure for a memory device, which may include the one or more steps 435 associated with the one or more layers of the metallic material 405, as described with reference to FIG. 4. For example, the step 435-a may be associated with the layer 440-a and the step 435-b may be associated with the layer 440-b. In some cases, the cavity 445-a and the cavity 445-b may be cut at least partially within the step 435-a and the step 435-b, respectively, and may extend through the stack and terminate at a staircase contact pad 425 (e.g., a rivet) or may extend to the corresponding layer 440 (e.g., a top down contact), which may be included in the first set of manufacturing instructions as described with reference to FIG. 4.

In some cases, the second set of manufacturing instructions may include exhuming a sacrificial material (e.g., the sacrificial material 430 described with reference to FIG. 4) from one or more exposed layers. For example, a portion of the layer 440-a that overlaps with the step 435-a may include the sacrificial material, which may be a second sacrificial material (e.g., SiCN) that is a transformed from a first sacrificial material (e.g., SiN) via implantation (e.g., implanting carbon). In some cases, the first sacrificial material and the second sacrificial material may have different etch chemistries, and may be etched separately. For example, the one or more layers of the metallic material 405 may initially be filled with the first sacrificial material, and may be exhumed separately from the exposed layer of the second sacrificial material. In some cases, the first sacrificial material may be exhumed via a slit, which may be formed in a location that is exclusive of the step cavity and the contact cavity (e.g., in a space between steps 435) and may be cut in a plane that is parallel or orthogonal to the cross section illustrated by the layout 500.

In some cases, the second sacrificial material may be exhumed to form a void that connects to a corresponding cavity 445 (e.g., a cavity 505-a and a cavity 505-b). For example, the second sacrificial material may be exhumed via a corresponding cavity 445 (e.g., as illustrated in the layout 500) to form the cavity 505-a and the cavity 505-b. As another example, the second sacrificial material may be exhumed via the slit and may be exhumed prior to depositing the metallic material 505 (e.g., and after exhuming the first sacrificial material via the slit). For example, after exhuming the first sacrificial material from the layer 440-a and prior to depositing the metallic material 405 in the layer 440-a, the second sacrificial material may be exhumed and the metallic material 405 may be deposited in the exposed portion of the layer 440-a (e.g., extending to the cavity 445-a on either side).

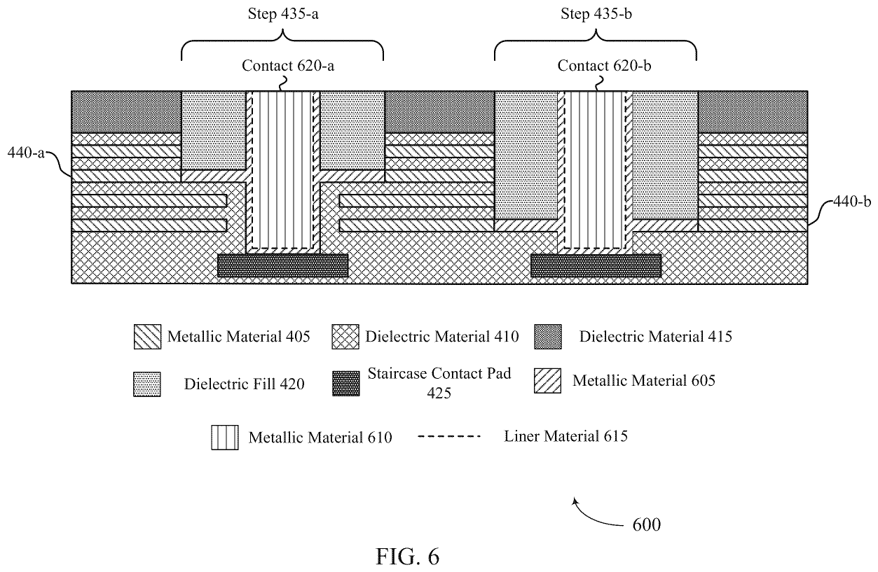

FIG. 6 shows an example of a layout 600 that supports low resistance staircase rivet contact using metal-to-metal strap connection in accordance with various aspects of the present disclosure. The layout 600 may illustrate an example of a third set of manufacturing operations for a memory device that supports a metal-to-metal strap connection at a word line contact as described herein. In some cases, the third set of manufacturing operations may follow the second set of manufacturing operations described with reference to FIG. 5 (e.g., applying the third set of manufacturing operations to the layout 500 may result in the layout 600). The layout 600 may include one or more aspects of the layouts 400 and 500, such as one or more layers of the metallic material 405 (e.g., a first metallic material), one or more layers of the dielectric material 410, a top layer of the dielectric material 415, the dielectric fill 420 (e.g., a same or different material as the dielectric material 415 and the dielectric material 410), the staircase contact pads 425, or any combination thereof, which may be examples of corresponding aspects described with reference to FIGS. 4 and 5. Additionally, the layout 600 may include a metallic material 605 (e.g., a second metallic material), a metallic material 610 (e.g., a third metallic material), a liner material 615, or any combination thereof. It should be noted that the layout 600 may support any quantity of layers, any type of material, and various patterns of the materials, among other examples. The layout 600 may include a cross section view of a memory device associated with the third set of manufacturing operations.

In some cases, the third set of manufacturing operations may include depositing the metallic material 605 to form one or more contacts 620. For example, the metallic material 605 may be deposited in cavities (e.g., the cavities 445 described with reference to FIGS. 4 and 5) corresponding to a contact 620-a and a contact 620-b, and may be deposited using a chemical vapor deposition (CVD) process or an atomic layer deposition (ALD) process. In some cases, the contacts 620 may extend through the stack and terminate at a corresponding staircase contact pad 425 (e.g., a rivet contact). In some other cases, the contacts 620 may extend through the stack and terminate at a corresponding layer 425 (e.g., a top down contact).

The metallic material 605 may be an example of a metallic material that can adhere to a dielectric material (e.g., an oxide material such as the dielectric material 410) using the CVD process or the ALD process. By way of example, some metallic materials (e.g., Tungsten) may flake or otherwise fail to adhere to the dielectric material 410 when deposited in contact with the dielectric material 410. In such examples, a liner material (e.g., TiN) may be deposited in between the metallic material and the dielectric material 410. However, such techniques may result in a greater resistance between the contact 620 and a corresponding layer 440 (e.g., due to the liner separating the direct connection). To support a reduced resistance between the contact 620 and the corresponding layer 440, the metallic material 605 may be chosen such that the metallic material 605 adheres to the dielectric material 410 using a CVD process or ALD process. For example, the metallic material 605 may be Molybdenum (e.g., or any other metallic material that can be deposited using a CVD process or an ALD process and adheres to the dielectric material 410 without usage of a resistive liner).

In some cases, the metallic material 605 may directly contact the metallic material 405 (e.g., to form a word line contact between a contact 620 and a corresponding layer 440). For instance, the third set of manufacturing instructions may include filling the portion of a layer 440 that is exposed by a step cavity (e.g., a strap of the layer 440 spanning the width of the cavity for a step 435) using various techniques. In one example, as illustrated in the layout 600, the strap may be filled with the metallic material 605. For example, as part of depositing the metallic material 605 to form the contact 620-a and the contact 620-b, the metallic material 605 may be deposited in the respective straps (e.g., extending to contact the metallic material 405 of the layer 440-a and the layer 440-b). As another example, the strap may be filled with the metallic material 405. For example, as part of depositing the metallic material 405 via the slit (e.g., after exhuming the second sacrificial material via the slit as described with reference to FIG. 5), the metallic material 405 may be deposited in the strap of the layers 440 (e.g., extending to the corresponding contact 620). Such techniques (e.g., filling the strap with the metallic material 405 or the metallic material 605) may mitigate a resistance between each contact 620 and a corresponding layer 440.

In some examples, the contacts 620 may be filled with the metallic material 605 (e.g., without another material present in the contacts 655). Additionally, or alternatively, the contacts 620 may be filled with the metallic material 610 (e.g., a plug of the metallic material 610 that is surrounded by the metallic material 605), as illustrated in the layout 600. For example, after depositing the metallic material 605 into the contacts 620 (e.g., covering the surface of the contacts 620), the metallic material 610 may be deposited in the contacts 620 within the remaining space of the contacts 620. In some cases, a liner material 615 may be deposited in the contacts 620 and may be located in between the metallic material 605 and the metallic material 610, as illustrated in the layout 600. For example, the liner material 615 (e.g., TiN) may be deposited after depositing the metallic material 605 and prior to depositing the metallic material 610, and may support a low-resistance contact (e.g., due to a relatively large surface area of the liner material 615).

FIG. 7 shows a block diagram 700 of a manufacturing system 720 that supports low resistance staircase rivet contact using metal-to-metal strap connection in accordance with examples as disclosed herein. The manufacturing system 720 may be an example of aspects of a manufacturing system as described with reference to FIGS. 1 through 6. The manufacturing system 720, or various components thereof, may be an example of means for performing various aspects of low resistance staircase rivet contact using metal-to-metal strap connection as described herein. For example, the manufacturing system 720 may include a stack formation component 725, a cavity formation component 730, a material deposition component 735, a material exhuming component 740, an implantation component 745, or any combination thereof. Each of these components may communicate, directly or indirectly, with one another (e.g., via one or more buses).

The stack formation component 725 may be configured as or otherwise support a means for forming, on a substrate, a stack of materials including a plurality of layers, the plurality of layers alternating between a first material and a second material, where the first material is a first dielectric material. The cavity formation component 730 may be configured as or otherwise support a means for forming a first cavity in the stack of materials, where a bottom of the first cavity exposes a layer of the plurality of layers of the second material. The material deposition component 735 may be configured as or otherwise support a means for filling the first cavity with a second dielectric material. In some examples, the cavity formation component 730 may be configured as or otherwise support a means for forming a second cavity in the stack of materials, the second cavity at least partially within the filled first cavity. In some examples, the cavity formation component 730 may be configured as or otherwise support a means for forming a third cavity in the stack of materials, the third cavity exclusive of the first cavity and the second cavity. The material exhuming component 740 may be configured as or otherwise support a means for exhuming, via the third cavity, the second material of the plurality of layers to form voids corresponding to the second material. In some examples, the material deposition component 735 may be configured as or otherwise support a means for depositing, via the third cavity, a first metallic material within the voids of the plurality of layers. In some examples, the material deposition component 735 may be configured as or otherwise support a means for depositing, via the second cavity, a second metallic material, where the second metallic material is in contact with the first metallic material and is deposited using a chemical vapor deposition process or an atomic layer deposition process.

In some examples, the implantation component 745 may be configured as or otherwise support a means for transforming the exposed layer of the plurality of layers from the second material to a third material prior to forming the second cavity.

In some examples, the material exhuming component 740 may be configured as or otherwise support a means for exhuming, via the third cavity, the third material of the exposed layer prior to depositing the first metallic material within the voids of the plurality of layers, where depositing the first metallic material via the third cavity includes depositing the first metallic material within a void formed by exhuming the third material of the exposed layer.

In some examples, the material exhuming component 740 may be configured as or otherwise support a means for exhuming, via the second cavity, the third material of the exposed layer, where depositing the second metallic material via the second cavity includes depositing the second metallic material within a void formed by exhuming the third material of the exposed layer.

In some examples, the material deposition component 735 may be configured as or otherwise support a means for filling the second cavity with a third metallic material.

In some examples, the material deposition component 735 may be configured as or otherwise support a means for depositing a fourth material in the second cavity prior to filling the second cavity with the third metallic material, where the fourth material is in between the second metallic material and the third metallic material.

In some examples, the second metallic material includes Molybdenum.

FIG. 8 shows a flowchart illustrating a method 800 that supports low resistance staircase rivet contact using metal-to-metal strap connection in accordance with examples as disclosed herein. The operations of method 800 may be implemented by a manufacturing system or its components as described herein. For example, the operations of method 800 may be performed by a manufacturing system as described with reference to FIGS. 1 through 7. In some examples, a manufacturing system may execute a set of instructions to control the functional elements of the device to perform the described functions. Additionally, or alternatively, the wireless manufacturing system may perform aspects of the described functions using special-purpose hardware.

At 805, the method may include forming, on a substrate, a stack of materials including a plurality of layers, the plurality of layers alternating between a first material and a second material, where the first material is a first dielectric material. The operations of 805 may be performed in accordance with examples as disclosed herein. In some examples, aspects of the operations of 805 may be performed by a stack formation component 725 as described with reference to FIG. 7.

At 810, the method may include forming a first cavity in the stack of materials, where a bottom of the first cavity exposes a layer of the plurality of layers of the second material. The operations of 810 may be performed in accordance with examples as disclosed herein. In some examples, aspects of the operations of 810 may be performed by a cavity formation component 730 as described with reference to FIG. 7.

At 815, the method may include filling the first cavity with a second dielectric material. The operations of 815 may be performed in accordance with examples as disclosed herein. In some examples, aspects of the operations of 815 may be performed by a material deposition component 735 as described with reference to FIG. 7.

At 820, the method may include forming a second cavity in the stack of materials, the second cavity at least partially within the filled first cavity. The operations of 820 may be performed in accordance with examples as disclosed herein. In some examples, aspects of the operations of 820 may be performed by a cavity formation component 730 as described with reference to FIG. 7.

At 825, the method may include forming a third cavity in the stack of materials, the third cavity exclusive of the first cavity and the second cavity. The operations of 825 may be performed in accordance with examples as disclosed herein. In some examples, aspects of the operations of 825 may be performed by a cavity formation component 730 as described with reference to FIG. 7.

At 830, the method may include exhuming, via the third cavity, the second material of the plurality of layers to form voids corresponding to the second material. The operations of 830 may be performed in accordance with examples as disclosed herein. In some examples, aspects of the operations of 830 may be performed by a material exhuming component 740 as described with reference to FIG. 7.

At 835, the method may include depositing, via the third cavity, a first metallic material within the voids of the plurality of layers. The operations of 835 may be performed in accordance with examples as disclosed herein. In some examples, aspects of the operations of 835 may be performed by a material deposition component 735 as described with reference to FIG. 7.

At 840, the method may include depositing, via the second cavity, a second metallic material, where the second metallic material is in contact with the first metallic material and is deposited using a chemical vapor deposition process or an atomic layer deposition process. The operations of 840 may be performed in accordance with examples as disclosed herein. In some examples, aspects of the operations of 840 may be performed by a material deposition component 735 as described with reference to FIG. 7.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming, on a substrate, a stack of materials including a plurality of layers, the plurality of layers alternating between a first material and a second material, where the first material is a first dielectric material; forming a first cavity in the stack of materials, where a bottom of the first cavity exposes a layer of the plurality of layers of the second material; filling the first cavity with a second dielectric material; forming a second cavity in the stack of materials, the second cavity at least partially within the filled first cavity; forming a third cavity in the stack of materials, the third cavity exclusive of the first cavity and the second cavity; exhuming, via the third cavity, the second material of the plurality of layers to form voids corresponding to the second material; depositing, via the third cavity, a first metallic material within the voids of the plurality of layers; and depositing, via the second cavity, a second metallic material, where the second metallic material is in contact with the first metallic material and is deposited using a chemical vapor deposition process or an atomic layer deposition process.

Aspect 2: The method, apparatus, or non-transitory computer-readable medium of aspect 1, further including operations, features, circuitry, logic, means, or instructions, or any combination thereof for transforming the exposed layer of the plurality of layers from the second material to a third material prior to forming the second cavity.

Aspect 3: The method, apparatus, or non-transitory computer-readable medium of aspect 2, further including operations, features, circuitry, logic, means, or instructions, or any combination thereof for exhuming, via the third cavity, the third material of the exposed layer prior to depositing the first metallic material within the voids of the plurality of layers, where depositing the first metallic material via the third cavity includes depositing the first metallic material within a void formed by exhuming the third material of the exposed layer.

Aspect 4: The method, apparatus, or non-transitory computer-readable medium of any of aspects 2 through 3, further including operations, features, circuitry, logic, means, or instructions, or any combination thereof for exhuming, via the second cavity, the third material of the exposed layer, where depositing the second metallic material via the second cavity includes depositing the second metallic material within a void formed by exhuming the third material of the exposed layer.

Aspect 5: The method, apparatus, or non-transitory computer-readable medium of any of aspects 1 through 4, further including operations, features, circuitry, logic, means, or instructions, or any combination thereof for filling the second cavity with a third metallic material.

Aspect 6: The method, apparatus, or non-transitory computer-readable medium of aspect 5, further including operations, features, circuitry, logic, means, or instructions, or any combination thereof for depositing a fourth material in the second cavity prior to filling the second cavity with the third metallic material, where the fourth material is in between the second metallic material and the third metallic material.

Aspect 7: The method, apparatus, or non-transitory computer-readable medium of any of aspects 1 through 6, where the second metallic material includes Molybdenum.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: An apparatus, including: a stack of materials including a plurality of layers, the plurality of layers alternating between a first material and a second material, the second material including a first metallic material, the stack of materials including a cavity at least partially filled with a third material, where a bottom of the cavity is in contact with a layer of the plurality of layers of the second material; and a contact extending at least partially through the stack of materials and at least partially within the filled cavity, the contact including a second metallic material that is in contact with the first metallic material of the layer of the plurality of layers.

Aspect 9: The apparatus of aspect 8, where the contact is lined with the second metallic material.

Aspect 10: The apparatus of aspect 9, where the contact is at least partially filled with a third metallic material.

Aspect 11: The apparatus of aspect 10, where the contact is at least partially filled with a fourth material, the fourth material between the third material and the second metallic material.

Aspect 12: The apparatus of any of aspects 8 through 11, where the contact extends through each layer of the plurality of layers of the stack of materials.

Aspect 13: The apparatus of any of aspects 8 through 12, where the contact extends partially through the stack of materials to a depth of the layer of the plurality of layers.

Aspect 14: The apparatus of any of aspects 8 through 13, where the second metallic material includes Molybdenum.

Aspect 15: The apparatus of any of aspects 8 through 14, where the first metallic material of the layer of the plurality of layers forms a plurality of word lines each coupled with respective pluralities of memory cells.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
forming, on a substrate, a stack of materials comprising a plurality of layers, the plurality of layers alternating between a first material and a second material, wherein the first material is a first dielectric material;
forming a first cavity in the stack of materials, wherein a bottom of the first cavity exposes a layer of the plurality of layers of the second material;
filling the first cavity with a second dielectric material;
forming a second cavity in the stack of materials, the second cavity at least partially within the filled first cavity;
forming a third cavity in the stack of materials, the third cavity exclusive of the first cavity and the second cavity;
exhuming, via the third cavity, the second material of the plurality of layers to form voids corresponding to the second material;
depositing, via the third cavity, a first metallic material within the voids of the plurality of layers; and
depositing, via the second cavity, a second metallic material, wherein the second metallic material is in contact with the first metallic material and is deposited using a chemical vapor deposition process or an atomic layer deposition process.

2. The method of claim 1, further comprising:
transforming the exposed layer of the plurality of layers from the second material to a third material prior to forming the second cavity.

3. The method of claim 2, further comprising:
exhuming, via the third cavity, the third material of the exposed layer prior to depositing the first metallic material within the voids of the plurality of layers, wherein depositing the first metallic material via the third cavity comprises depositing the first metallic material within a void formed by exhuming the third material of the exposed layer.

4. The method of claim 2, further comprising:
exhuming, via the second cavity, the third material of the exposed layer, wherein depositing the second metallic material via the second cavity comprises depositing the second metallic material within a void formed by exhuming the third material of the exposed layer.

5. The method of claim 1, further comprising:
filling the second cavity with a third metallic material.

6. The method of claim 5, further comprising:
depositing a fourth material in the second cavity prior to filling the second cavity with the third metallic material, wherein the fourth material is in between the second metallic material and the third metallic material.

7. The method of claim 1, wherein the second metallic material comprises Molybdenum.

8. An apparatus, comprising:
a stack of materials comprising a plurality of layers, the plurality of layers alternating between a first material and a second material, the second material comprising a first metallic material, the stack of materials comprising a cavity at least partially filled with a third material, wherein a bottom of the cavity is in contact with a layer of the plurality of layers of the second material; and
a contact extending at least partially through the stack of materials and at least partially within the cavity, the contact comprising a second metallic material that is in contact with the first metallic material of the layer of the plurality of layers.

9. The apparatus of claim 8, wherein the contact is lined with the second metallic material.

10. The apparatus of claim 9, wherein the contact is at least partially filled with a third metallic material.

11. The apparatus of claim 10, wherein the contact is at least partially filled with a fourth material, the fourth material between the third material and the second metallic material.

12. The apparatus of claim 8, wherein the contact extends through each layer of the plurality of layers of the stack of materials.

13. The apparatus of claim 8, wherein the contact extends partially through the stack of materials to a depth of the layer of the plurality of layers.

14. The apparatus of claim 8, wherein the second metallic material comprises Molybdenum.

15. The apparatus of claim 8, wherein the first metallic material of the layer of the plurality of layers forms a plurality of word lines each coupled with respective pluralities of memory cells.

16. An apparatus, comprising:
a stack of materials comprising a plurality of layers comprising a first material and a second material, the second material comprising a first metallic material, the stack of materials comprising a cavity at least partially filled with a third material, wherein a bottom of the cavity is in contact with a layer of the plurality of layers of the second material; and
a contact extending at least partially through the stack of materials and at least partially within the cavity, the contact comprising a second metallic material that is in contact with the first metallic material of the layer of the plurality of layers.

17. The apparatus of claim 16, wherein the contact is lined with the second metallic material.

18. The apparatus of claim 17, wherein the contact is at least partially filled with a third metallic material.

19. The apparatus of claim 18, wherein the contact is at least partially filled with a fourth material, the fourth material between the third material and the second metallic material.

20. The apparatus of claim 16, wherein the contact extends through each layer of the plurality of layers of the stack of materials.
